(19) United States
(12) Patent Application Publication
(10) Pub. No.: US 2024/0345487 A1
(43) Pub. Date: Oct. 17, 2024

(54) METHOD OF EVALUATING SELECTED SET OF PATTERNS

(71) Applicant: ASML NETHERLANDS B.V., Veldhoven (NL)

(72) Inventors: Rencheng SUN, Shenzhen (CN); Feng YANG, Shenzhen (CN); Meng LIU, Shenzhen (CN); Fei YAN, Shenzhen (CN)

(21) Appl. No.: 18/681,613

(22) PCT Filed: Aug. 2, 2022
(86) PCT No.: PCT/EP2022/071659

§ 371 Date: Feb. 6, 2024

(30) Foreign Application Priority Data
Sep. 2, 2021 (WO) PCT/CN2021/116215

(51) Int. Cl. G03F 7/00

(52) U.S. Cl. CPC G03F 7/705; G03F 7/70441

(57) ABSTRACT

Systems and methods for evaluating selected set of patterns of a design layout. A method herein includes obtaining (i) a first pattern set resulting from a pattern selection process, (ii) first pattern data associated with the first pattern set, (iii) characteristic data associated with the first pattern data, and (iv) second pattern data associated with a second pattern set. A machine learning model is trained based on the characteristic data, where the machine learning model being configured to predict pattern data for an input pattern. The second pattern set is input to the trained machine learning model to predict second pattern data of the second pattern set. The first pattern set is evaluated by comparing the second pattern data and the predicted second pattern data. If the evaluation indicates insufficient pattern coverage, additional patterns can be included to improve the pattern coverage.

### CROSS-REFERENCE TO RELATED APPLICATIONS

This application claims priority of International application PCT/CN2021/116215 which was filed on Sep. 2, 2021 and which is incorporated herein in its entirety by reference.

### TECHNICAL FIELD

The description herein relates generally to improving metrology measurements and lithography related processes. More particularly, apparatuses, methods, and computer program products for evaluating a set of patterns for metrology measurements or training models used in patterning process.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involve processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

In an embodiment, there is provided a method for evaluating a selected set of patterns from a design layout, for example, for purposes of performing metrology measurements and/or generating a training data set for computational lithography machine learning models. Taking measurements on a patterned substrates using metrology tools is a time-consuming process and affects throughput (e.g., number of chips manufactured per hour) of the semiconductor manufacturing process. Typically, there may be millions of patterns on a design layout desired to be printed on a chip. Measuring all these patterns within a desired time to meet the throughput specification of the semiconductor manufacturing process is impractical. Hence, a reduced set of patterns are usually selected from the design layout for measurement.

These measurements may be for various purposes related to a patterning process. In an embodiment, the measurements may be used for monitoring or adjusting a patterning process of the semiconductor manufacturing process. In an embodiment, the measurements may be used for model calibration or training models related to the patterning process. As such, the reduced set of patterns selected for metrology measurements may be evaluated so even with reduced measurements, accurate control and adjustments to the patterning process may be achieved.

Additionally, even with reduced measurements accurate model calibration or model training may be achieved. This also helps reduce the computation time and resources used during the model calibration or model training.

For example, if the selected set of patterns are representative of the millions of patterns of the design layout, or the pattern set has adequate pattern coverage, when metrology measurements of such set of patterns are used for training a model related to a patterning process, the trained model may accurately predict characteristics of the patterned substrate. The present disclosure provides mechanism for evaluating one or more selected pattern sets without relying on the metrology data thereof. The pattern sets may each result from a pattern selection process. In this manner, the evaluation can be performed advantageously before the time-consuming metrology measurement.

According to an embodiment, a method for evaluating a selected set of patterns is provided. The method includes obtaining (i) a first pattern set resulting from a pattern selection process, (ii) first pattern data associated with the first pattern set, (iii) characteristic data associated with the first pattern data, and (iv) second pattern data associated with a second pattern set. A machine learning model is trained based on the characteristic data associated with the first pattern, where the machine learning model being configured to predict pattern data for a pattern input into the machine learning model. The second pattern set is input to the trained machine learning model to predict second pattern data of the second pattern set. The first pattern set is evaluated by comparing the second pattern data and the predicted second pattern data. The first pattern set comprises a first plurality of patterns of a design layout, and the second pattern set comprises a second plurality of patterns of the design layout. In an embodiment, the second pattern set comprises a full chip layout

In an embodiment, obtaining the first pattern data involves generating first contours or first images by executing a reference model configured to simulate a patterning process using the first pattern set as input. Similarly, obtaining the second pattern data involves generating second contours or second images by executing a reference model configured to simulate a patterning process using the second pattern set as input.

In an embodiment, the first pattern set may be a subset of the second pattern set.

In an embodiment, evaluating of the first pattern set involves computing a difference between the second pattern data and the predicted second pattern data. In an embodiment, an absolute pattern coverage is determined as a function of an absolute error associated with the trained machine learning model trained using the first pattern set. In an embodiment, a relative pattern coverage may be determined as a function of a relative error, the relative error being a comparison between a first error range associated with the trained machine learning model trained using the first pattern set, and a second error range associated with another pattern set.

In an embodiment, risk patterns within the design layout may be determined. The risk patterns being associated with model prediction errors breaching a desired error threshold. These risk pattern may be supplemented to the first pattern set to improve the pattern coverage.

Once, it is evaluated that the selected set of patterns have sufficient coverage, the selected set of patterns may be employed for various purposes related to a patterning process or a metrology process. For example, the selected pattern set may be used to capture, via a metrology tool, measurements of a patterned substrate. Advantageously, the selected pattern improves the metrology throughput. As another example, the selected set of patterns may be used for training a ML model related to a patterning process.

According to an embodiment, there is provided a computer system comprising a non-transitory computer readable medium having instructions recorded thereon. The instructions, when executed by a computer, implement the method steps above.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed embodiments. In the drawings,

FIG. 1 illustrates a block diagram of various subsystems of a lithographic projection apparatus, according to an embodiment.

FIG. 2 illustrates a flow chart of an exemplary method for simulating lithography in a lithographic projection apparatus, according to an embodiment.

FIG. 3 is a block diagram of a evaluating process of a given set of patterns of a design layout, according to an embodiment.

FIG. 4 is an exemplary flowchart of a method for evaluating a given set of patterns (e.g., a subset of patterns) of a design layout, according to an embodiment.

FIG. 5 is a box plot of contour-to-contour defect size associated with different selected pattern sets, according to an embodiment.

FIG. 6 illustrates absolute and relative pattern coverage check based on a defect size, the defect size being associated with different pattern sets obtained from different pattern selection processes, according to an embodiment.

FIG. 7 illustrates relative comparison of different pattern sets based on contour-to-contour error ranges where different pattern sets are obtained from different pattern selection processes, according to an embodiment.

FIG. 8 illustrates identifying risk pattern based on trained machine learning model errors, according to an embodiment.

FIG. 9 is a block diagram of an example computer system, according to an embodiment.

FIG. 10 is a schematic diagram of an exemplary extreme ultraviolet (EUV) lithographic projection apparatus, according to an embodiment.

FIG. 11 is a schematic diagram of another lithographic projection apparatus, according to an embodiment.

FIG. 12 is a more detailed view of the exemplary apparatus in FIG. 11, according to an embodiment.

FIG. 13 is a more detailed view of the source collector module of the apparatus of FIG. 11 and FIG. 12, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” may be used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.

An example of a programmable LCD array is given in U.S. Pat. No. 5,229,872, which is incorporated herein by reference.

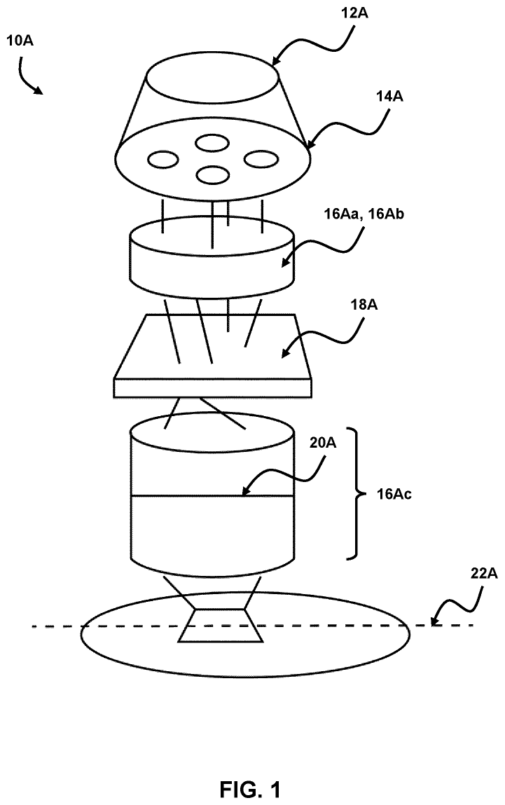

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin (Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

According to an embodiment of the present disclosure, one or more images may be generated with various types of signals corresponding to pixel values (e.g., intensity values) of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image). In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be a signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

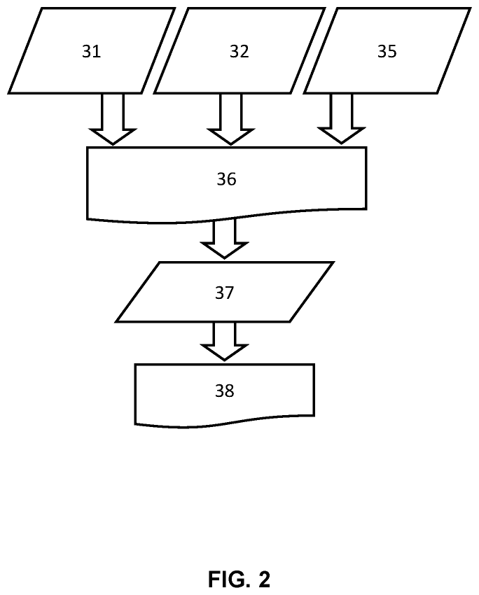

FIG. 2 illustrates an exemplary flow chart for simulating lithography in a lithographic projection apparatus, according to an embodiment. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (o) settings as well as any particular illumination shape (e.g. off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas. These clips or reduced set of patterns therein may be further used for different purposes related to a patterning process or metrology measurements.

As used herein, the term “patterning process” generally means a process that creates an etched substrate by the application of specified patterns of light as part of a lithography process. However, “patterning process” can also include plasma etching, as many of the features described herein can provide benefits to forming printed patterns using plasma processing.

As used herein, the term “design pattern” or “target pattern” means an idealized pattern that is to be etched on a substrate. The term “target layout” refers to a design layout comprising one or more target patterns.

As used herein, the term “printed pattern” or “patterned substrate” means the physical pattern on a substrate that was imaged and/or etched based on a target pattern. The printed pattern can include, for example, troughs, channels, depressions, edges, or other two and three dimensional features resulting from a lithography process.

As used herein, the term “process model” means a model that includes one or more models that simulate a patterning process. For example, a process model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), and an OPC model (e.g., that can be used to modify target patterns to include sub-resolution resist features (SRAFs), etc.).

Oftentimes, in training a patterning process model, controlling patterning process or other applications, or other semiconductor manufacturing related processes, a subset of patterns of a design layout are selected and used in order to improve throughput of metrology measurements. As an example, a reduced pattern set reduces metrology measurement or modeling time and improves throughput. For example, in order to improve the patterning process and patterning accuracy, process models are trained using target patterns, mask patterns, substrate images, etc. The OPC process may include one or more trained models to generate better mask patterns, such as an optical model, mask model, resist model, etch model, etc. For example, OPC assisted by machine learning significantly improves the accuracy of full chip assist feature (e.g., SRAF) placement while keeping consistency and runtime of the mask design under control. A deep convolutional neural network (DCNN) can be trained using the target layout or target patterns therein, and corresponding continuous transmission mask (CTM) images. These CTM images are optimized using an inverse mask optimization simulation process. The CNN generated SRAF guidance map is then used to place SRAF on full-chip design layout.

When choosing a set of patterns for training, it is desired to select a set of patterns that will be most informative for the model. Currently, several approaches are available for pattern selection. For example, a pattern hashing techniques may be fast, but works best in exact matching, rather than capturing pattern similarity. In another example, unsupervised image based pattern imaging techniques (e.g., Auto-Encoder based) may capture pattern similarities in a higher multi-dimensional latent space. In a model simulation based pattern classification and selection technique, aerial image or resist image parameter space may be used that incorporates similarities from a model simulation perspective.

This disclosure provide a mechanism of evaluating performance achieved by the selected set of patterns or the reduced pattern set of the design layout before collecting wafer metrology data. The evaluation can be used to verify pattern coverage, evaluate pattern selection processes, compare different selected pattern sets, or improve pattern coverage. Advantageously, evaluating the selected set of patterns can provide insights into whether the selected set of patterns have good enough pattern coverage of the design layout, whether more patterns should be added to improve the pattern coverage, or improving other aspects of the patterning process or metrology process. As an example, improving the pattern coverage will in turn make the metrology measurements more effective. As another example, improving pattern coverage will improve training time as well as quality of predictions made by a trained process model. For example, the trained process model can accurately predict contours of patterned substrate for an entire design layout.

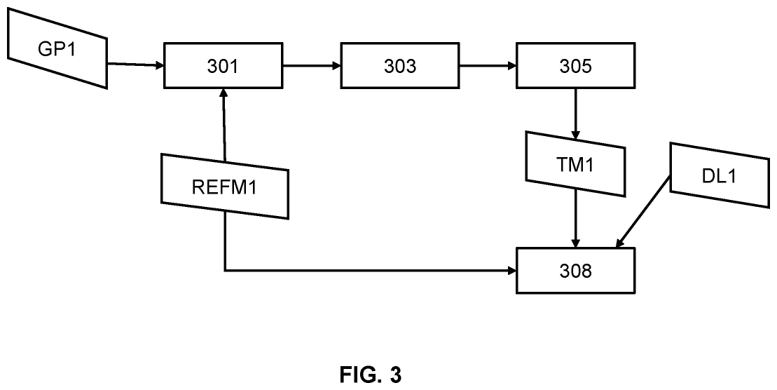

In the present embodiment, mechanisms for evaluating a selected set of patterns of a design layout are provided. For example, FIG. 3 is a block diagram of an evaluating process of given patterns of a design layout by training and executing a machine learning model, according to an embodiment.

In an embodiment, a subset of patterns of a design layout may be obtained by any suitable means. For example, the subset of patterns of the design layout may be provided by a user or selected using a pattern selection process. The subset of patterns of the design layout may be referred as a given pattern set GP1, a first pattern set GP1, or a reduced pattern set GP1 of the design layout. A reference model may be applied on the given pattern set GP1 to generate or extract pattern data used for training a machine learning (ML) model. For example, the pattern data may include simulated contours, gauges for measuring characteristics of a pattern, statistics associated with physical characteristics of the pattern, individual locations of the patterns, relative location of a pattern with other patterns, or other pattern related data that can be used for training a ML model. The trained ML model may be used for different applications related to a patterning process.

In an embodiment, the reference model can generate simulated contours of the given pattern set GP1, from which gauge data are derived. The gauge data is then used as training data for training the ML model. The trained ML model is then applied on a second pattern set to generate or extract a second pattern data (e.g., contours or other prediction results). The second pattern set is different than the given pattern set GP1, and may be a significantly larger pattern set than the given pattern GP1, e.g., a full-chip data set. The reference model is also applied on the second pattern set to generate corresponding first pattern data. The first pattern data resulting from the two models are compared and the difference is used to evaluate the given pattern set GP1 with respect to the ML model training. In some embodiments, both models are configured to predict contours for the second pattern set. Contour-to-contour comparison of the second data set between the two models is used for the pattern coverage evaluation.

More specifically, as shown in FIG. 3, at operation 301, a reference model REFM1 associated with a patterning process may be applied on the given patterns GP1 to generate simulated contours of the given patterns GP1. The present disclosure is not limited to any specific form of input data to the models. Depending on the implementation and the configuration of the REFM1, the input data may be polygons of target pattern or rendered images of the pattern set GP1. The reference model REFM1 may include one or more of, but not limited to, optics model, mask model, resist model, etch model, etc. The reference model may be a trained machine learning model or a calibrated non-machine learning model (e.g., physics-based model or an empirical model). In some other embodiment, at 301, contours of the given pattern GP1 may be obtained from metrology data (e.g., images) captured during measurement of a previously patterned substrate and metrology data was stored in a database.

At operation 303, gauges are configured to extract characteristic data associated with a pattern. For example, the gauges may be edge placement (EP) gauges or points placed at the contours, for example, characterize a shape and/or size of the contour. As another example, the gauges may be critical dimension gauges (CD gauges), gauges configured to measure pitches, spaces, curvature or other physical characteristics of a pattern.

At operation 305, the gauges may be used to train a ML model such that the trained ML model closely matches reference data such as an output of the reference model REFM1. The machine learning model may be a convolutional neural network, or any other suitable model configurations. The present disclosure is not limited to a particular machine learning model. The machine learning model may be trained using ML algorithms such as supervised or unsupervised learning. As an example, a ML model (e.g., CNN or DCNN) is trained by using the simulated EP gauge data. In other words, the trained ML is configured to mimic the outputs of the reference model REFM1.

At operation 308, the trained ML model may be applied to predict contours of a second pattern set different than GP1. The second data set includes any number of patterns without departing from the scope of the present disclosure. In some embodiments, it may be significantly larger than GP1. In some embodiments, the second pattern set may be a full chip layout. Also, the reference model REFM1 may be applied to generate a second contour set for the second pattern set. The ML predicted contours may be compared with the reference model-generated contours to evaluate the performance of the machine learning model which is used as performance evaluation of the given pattern set GP1. For example, a full chip contour-to-contour (C2C) comparison between the reference model-generated contours and the trained ML model-generated contours is used to characterize pattern coverage of GP1.

As an example, if the given pattern set GP1 has good pattern coverage characteristics, then the trained ML model may provide good predictions for new patterns of the design layout that were not included in the given pattern set. For example, if the design layout comprises more than 1 million patterns, while the given pattern set GP1 includes 10,000 patterns that are representative of the 1 million patterns, then the trained ML model can make good predictions (e.g., contours that may be patterned on the substrate) for the 1 million patterns. In other words, the predictions of the trained ML model will be associated with low error values. For example, the error values may be characterized by C2C differences between the ML predicted contours and the reference contours (e.g., generated by the reference model REFM1). The error values may be characterized by root mean square (RMS), standard deviation, a range (e.g., between minimum and maximum values), a distribution of the error values, or other ways to characterize an error associated with model predictions.

On the other hand, if the given pattern set GP1 has a poor pattern coverage, then the trained ML model may provide poor predictions for the new patterns not included in the first pattern set. In other words, the predictions of the trained ML model will be associated with high error values with reference to the reference model prediction. For example, the C2C differences between the ML predicted contours and the reference contours will be high.

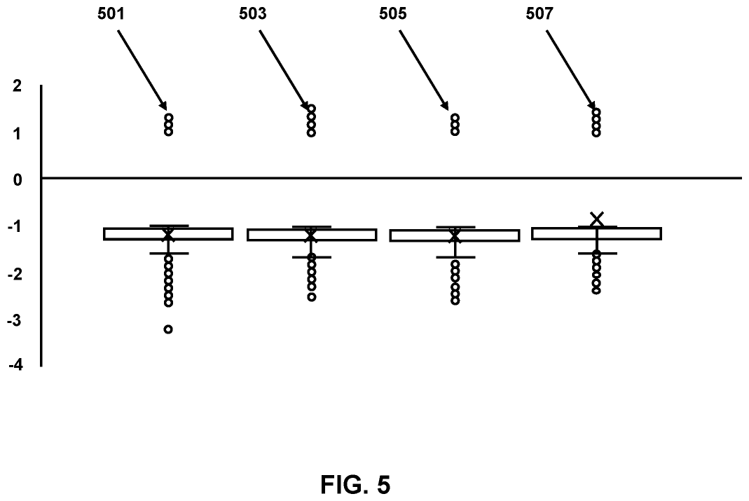

FIG. 5 illustrates an exemplary metric characterizing pattern coverage when different ML models are trained using different given patterns. The metric may be C2C differences for a full chip set, RMS of error values, standard deviation, etc. In the present discussion, C2C differences is used an example without limiting the scope of the present disclosure to a particular metric. A first given pattern set 501 may be used for training the ML model. When the trained ML model is applied to the full chip layout, C2C differences (e.g., between ML-predicted contours and reference contours) may be high. The plot provides a visualization of outliers. In an embodiment, values significantly away from a mean value may be an outlier. For example, values, greater than 1 or less than −2.5. These outliers may correspond to patterns that were not included in the first given pattern set 501. Thus, indicating that the given pattern set 501 do not have sufficient pattern coverage and additional pattern should be included to improve the pattern coverage. Similarly, different ML models may be trained using the pattern sets 503, 505, and 507, respectively, and respective C2C differences may be evaluated to determine pattern coverage performance of respective pattern sets. In some embodiment, the evaluation results of the ML models are compared to select the corresponding optimum pattern set.

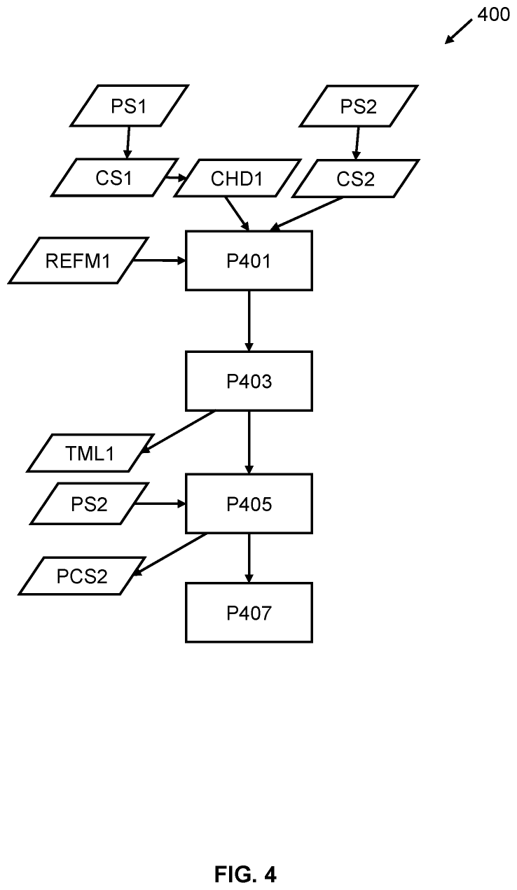

In an embodiment, the C2C results can also identify outlier patterns associated with high model errors. These identified C2C outlier patterns can be added to the given patterns GP1 as training data for retraining the ML model or training a new ML model. Evaluation of the given pattern set GP1 or the first pattern set is further discussed in detail with respect to FIGS. 4-8.

FIG. 4 is an exemplary flowchart of a method 400 for evaluating the performance of a selected pattern set of a design layout with respect to machine learning model training, according to an embodiment. In an embodiment, the evaluating is based on training of a ML model to predict characteristics (e.g., contours) of any input patterns. An example implementation of the method 400 is discussed with respect to processes P401, P403, P405, and P407.

Process P401 involves obtaining data associated with a first pattern set PS1 that will be used for training a ML model. The first pattern set PS1 is a pattern to be evaluated. In an embodiment, the process P401 involves obtaining a first pattern set PS1 resulting from a pattern selection process, and first pattern data (e.g., first contours CS1) associated with the first pattern set PS1. The present discussion uses contours as an exemplary pattern data for explaining the concepts of the present disclosure. However, the scope of the present disclosure is not limited to contours, and other forms of pattern data (e.g., images) may be used. The pattern data generated or extracted for a set of pattern/pattern set may depend on configuration of the input and output of the ML model. The pattern data (contours, gauge data or images) may be derived from mask images, aerial images, after etch images, or after development images resulting from the corresponding simulation or modeling.

In an embodiment, the process P401 may further involve obtaining characteristic data CHD1 associated with the first contours CS1. In an embodiment, the characteristic data CHD1 may be used for training the ML model. In an embodiment, the process P401 may further involve obtaining second pattern data (e.g., second contours CS2) associated with a second pattern set PS2 (e.g., a full chip layout). In an embodiment, the first pattern set PS1 and the second pattern set PS2 are selected from the same design layout. However, in some other embodiments, the pattern sets PS1 and PS2 may be included in different design layouts.

In an embodiment, the first pattern set PS1 may be a subset of the second pattern set PS2 selected from the design layout. In an embodiment, the first pattern set PS1 and the second pattern set PS2 may include a few common patterns selected from the design layout. In an embodiment, the first pattern set PS1 may be different from second pattern set PS2, but both sets selected from the design layout. In an embodiment, the first pattern set PS1 comprises a first plurality of patterns of a design layout, and the second pattern set PS2 comprises a second plurality of patterns of the design layout. In an embodiment, the second pattern set PS2 comprises more patterns than the first pattern set PS1. In an embodiment, the second pattern set PS2 comprises a full chip layout.

In an embodiment, obtaining the first contours CS1 involves generating the first contours CS1 by executing a reference model REFM1 configured to simulate a patterning process using the first pattern set PS1 as input. In an embodiment, obtaining the second contours CS2 involves generating the second contours CS2 by executing a reference model REFM1 configured to simulate a patterning process using the second pattern set PS2 as input.

In an embodiment, the reference model REFM1 comprises one or more constituent models characterizing the patterning process. For example, the reference model REFM1 may include, but not limited to, optics model, mask model, resist model, etch model, ML-resist model, ML-etch model, etc. Accordingly, the first contours CS1 and the second contours CS2 may be, for example, resist contours or etch contours at a substrate-level. In an embodiment, the first contours CS1 and second contours CS2 may be aerial image contours, mask image contours. As mentioned herein, the scope of the present disclosure is not limited to contours, and other type of pattern data may be generated for or extracted from a pattern set. In an embodiment, the reference model REFM1 may be a non-machine learning model such as physics and/or empirical based models.

In another embodiment, obtaining the first contours CS1 and the second contours CS2 involves obtaining contours from images of a previously patterned substrate previously captured by a metrology tool and stored in a database. In an embodiment, such previously patterned substrate may include the first pattern set PS1 and the second pattern set PS2 of a design layout.

In an embodiment, the characteristic data CHD1 may be gauges generated from the first contours CS1. In an embodiment, the gauges may be configured to quantify one or more physical characteristic of a pattern. For example, the gauges may be edge placement gauges located at a plurality of locations along a contour of the first contours CS1; critical dimension (CD) gauges configured to measure CD values of the first contours CS1; gauges configured to measure lines; gauges configured to measure spaces; gauges configured to measure tip-to-tip structures; and/or gauges configured to measure contour differences.

Process P403 involves training a ML model based on the characteristic data CHD1 associated with the first contours CS1. The ML model is configured to predict a contour responsive to a pattern input. In an embodiment, an existing machine learning algorithm (e.g., supervised or unsupervised learning techniques) may be employed to train the ML model. The ML model may be, but not limited to, a convolutional neural network (CNN or DCNN). For example, the training of the CNN may employ a cost function to determine weights of different layers of the CNN. As an example, the cost function may be a function of the EP gauges. During the training process, the EP gauges or a given pattern set may be input to the CNN, and the CNN generates predicted contours. Based on the predicted contours, the cost function such as edge placement error between predicted contours and reference contours may be evaluated and weights may be adjusted to minimize (or maximize) the cost function. After training the ML model, the ML model may be referred as a trained ML model TML1.

Process P405 involves generating predicted second contours PCS2 of the second pattern set PS2 by inputting the second pattern set PS2 to the trained ML model TML1.

Process P407 involves evaluating the first pattern set PS1 by comparing the second contours CS2 and the predicted second contours PCS2. In an embodiment, evaluating of the first pattern set PS1 involves computing a difference between the second contours CS2 and the predicted second contours PCS2. In an embodiment, the second contours CS2 may be associated with a full chip layout and the predicted second contours PCS2 may be predicted by inputting the full chip layout to the trained ML model TML1. Based on these contours, the first pattern set PS1 may be evaluated, for example, based on statistics (e.g., outliers, variations, mean values, median values, a distribution, etc.) associated with the C2C differences between contours CS2 and PCS2.

In an embodiment, evaluating of the first pattern set PS1 involves determining whether the difference breaches a difference threshold (e.g., user-defined or statistics-based); and responsive to the difference not breaching of the difference threshold, classifying the first pattern set PS1 as having good pattern coverage. As such, the first pattern PS1 may be considered acceptable for performing metrology in order to save metrology time, while obtaining good metrology measurements for improving patterning process.

In an embodiment, evaluating of the first pattern set PS1 involves determining an absolute pattern coverage as a function of an absolute error associated with the trained machine learning model trained directly using the second pattern set PS2. In an embodiment, evaluating of the first pattern set PS1 involves determining a relative pattern coverage as a function of a relative error. For example, the relative error may be a comparison between a first error range associated with a trained machine learning model trained using the first pattern set PS1, and a second error range associated with another trained machine learning model using another pattern set.

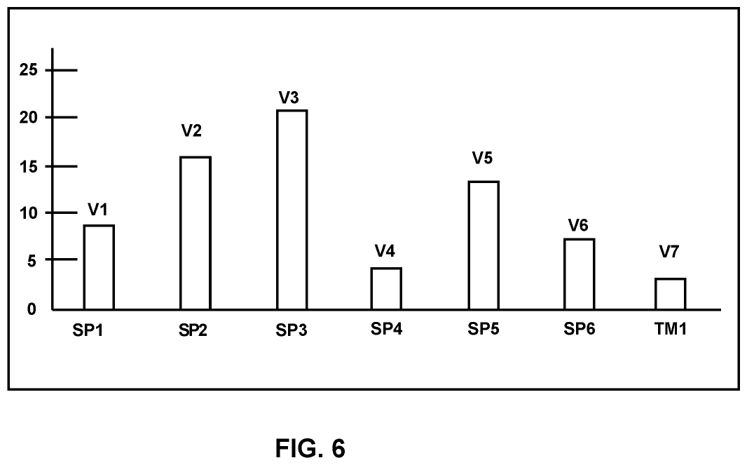

FIG. 6 illustrates absolute and relative pattern coverage check based on C2C errors, where the C2C errors are associated with different pattern sets obtained from different pattern selection processes, according to an embodiment. In FIG. 6, a bar TM1 correspond to a baseline model error associated with a trained machine learning model (e.g., TML1). In an embodiment, the baseline model error refers to an error in ML-model predictions when a full chip pattern set is used for training the ML model. For example, the full chip pattern may be used as input to the reference model to generate simulated contours and corresponding gauges. These gauges may be used to train the ML model. The trained ML model may be further applied to the full chip pattern to predict contours that may be printed on a substrate. When C2C difference between the predicted contour and the simulated contours (from reference model) is computed, the difference should ideally be zero. However, there may be a small, non-zero C2C difference, which is referred as a baseline model error. In the present example, the bar TM1 corresponds to such baseline model error.

In example illustrated in FIG. 6, a first bar SP1 corresponds to C2C differences between a trained ML model predicted contours and reference contours when a first pattern set is used for training a ML model. For example, the first pattern set may include approximately 200 patterns selected (using a first pattern selection method) from 1500 patterns of a DRAM design layout. Similarly, a second bar SP2 corresponds to C2C difference between a trained ML model predicted contours and reference contours when a second pattern set is used for training the ML model. For example, the second pattern set may include approximately 200 patterns selected (using a second pattern selection method) from 1500 patterns of a DRAM design layout. Similarly, each of a third bar SP3, a fourth bar SP4, a fifth bar SP5, and a sixth bar SP6 corresponds to C2C difference between a trained ML model predicted contours and reference contours when different pattern sets are used for training the ML model. Each of the pattern set selected using a different method and may include same or different number of patterns.

In an embodiment, the absolute values of the C2C differences V1, V2, V3, V4, V5, and V6 corresponding to the pattern sets SP1, SP2, SP3, SP4, SP5, and SP6, respectively, may indicate an absolute error associated with the respective pattern sets. A low absolute error (e.g., close to the baseline model error) is desirable, as it indicates a good pattern coverage is provided by that particular pattern set. In an embodiment, a threshold error value may be set for comparing with the individual model errors to evaluate whether a particular pattern set provides a good pattern coverage.

In an embodiment, each of the values V1-V6 may be compared to the baseline model error V7 to evaluate relative error associated with a particular pattern with respect to the baseline model error. In an embodiment, a pattern set associated with error value close to the baseline model error indicates that the pattern set provides a good pattern coverage. For example, the fourth pattern set (corresponding to the bar SP4) is associated with an error value V4, which is substantially close to the value V7. Hence, the fourth pattern set may be considered to provide a good pattern coverage. In an embodiment, the relative error may be analyzed between values V1-V6. Among the different pattern sets, the pattern set with relatively lower error than others may be considered as having a better pattern coverage.

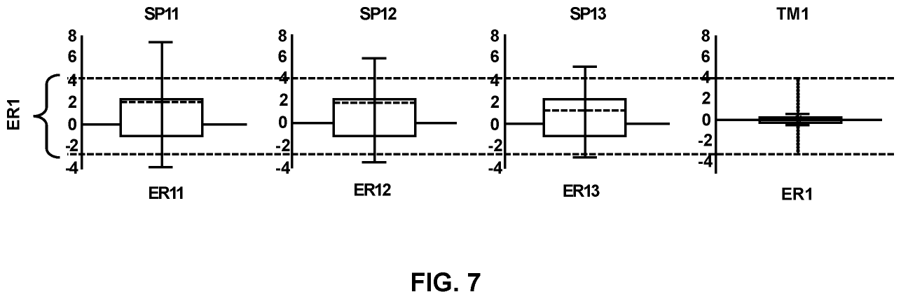

FIG. 7 illustrates another way to evaluate absolute and relative pattern coverage characteristics of a selected pattern set based on an error range. Similar to discussion in FIG. 6, a reference error range (e.g., a C2C difference range) associated with a trained ML model that is trained using full chip patterns may be determined. For example, a reference error range may be represented as ER1, in FIG. 7. In an embodiment, an error range is a range between a positive maximum error value and a negative maximum error value. An error range associated with each different selected pattern set may be determined. For example, an error range may be computed based on C2C difference between trained models predicted contours and reference contours. For example, a pattern set SP11 may be associated with an error range ER11, another pattern set SP12 may be associated with an error range ER12, and yet another pattern set SP13 may be associated with an error range ER13. FIG. 7 illustrates that the error range ER13 is smaller compared to ranges ER11 and ER12 indicating that the pattern set SP13 provides a better pattern coverage compared to other pattern sets. The error range ER13 is also substantially close to the error range ER1 indicating the pattern set SP13 likely provides sufficient pattern coverage for full chip patterns.

Referring back to FIG. 4, at process 407, evaluating of the first pattern set PS1 involves determining risk patterns within a design layout, according to an embodiment. In an embodiment, a risk pattern refers to a pattern prone to predictions errors by reference model, the baseline ML model, or other models related to a patterning process. In an embodiment, the risk patterns may be labeled as outliers (e.g., associated with difference values breaching a risk threshold). In an embodiment, such risk patterns may be included in the first pattern set to improve the pattern coverage.

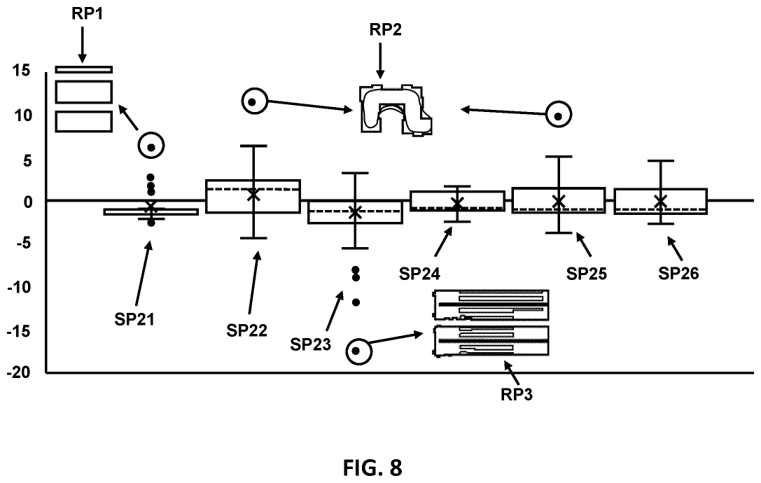

FIG. 8 illustrates identifying risk patterns based on errors resulting from trained machine learning models, according to an embodiment. In an embodiment, the risk patterns refer to a pattern prone to prediction errors by the reference model, the baseline ML model, or other models related to a patterning process. In an embodiment, the outlier error values may be characterized by C2C difference between reference contours and ML-predicted contours. In an embodiment, the outlier error values may be identified based on standard deviation, comparing the values with mean values (an example threshold), or other statistical ways to determine outliers in a data set.

In FIG. 8, the C2C difference between the trained ML model-generated and the reference contours is plotted for visual reference. As discussed herein, the C2C difference may be computed using a trained ML model that are trained using selected set of patterns such as SP21, SP22, SP23, SP24, SP25, or SP26. For each selected pattern set SP21-SP26, a different ML model may be trained. The trained ML model is then used to predict contours of a design layout and determine the C2C difference.

The C2C difference plot provides a visual representation of the outliers that can be identified. However, it will be appreciated by those skilled in the art that outliers can be identified without visual representation in some embodiments. The patterns corresponding to such outliers may be the risk patterns. Based on which selected set of patterns are used for training the ML model, different risk patterns may be identified. For example, when SP21 is used for training the ML model, a risk pattern RP1 is identified from the design layout. Similarly, risk patterns RP2 and RP3 may be identified from the design layout.

In an embodiment, the method 400 involves identifying, based on the first pattern set PS1, a list of patterns (e.g., risk patterns, hotspots, etc.) to be examined by a metrology tool. In an embodiment, the measured data related to the list of patterns may be further used to train or calibrate a ML model related to a patterning process.

In an embodiment, the method 400 involves identifying locations of the second pattern set PS2 corresponding to breach in the difference threshold, supplementing the first pattern set PS1 with one or more patterns associated with the identified locations; and training another machine leaning model using the supplemented first pattern set PS1. In an embodiment, the supplemented first pattern set PS1 correspond a higher pattern coverage compared to the first pattern set PS1.

In an embodiment, the metrology tool determines metrology measurements including, but not limited to, critical dimension, overlay, and edge placement error associated with the first pattern set PS1 or the supplemented first pattern set of the design layout patterned on the substrate. These measurements may be further used to control the lithographic processes, train a machine learning model to generate mask patterns (e.g., defect detection model, etch model, resist model, OPC, SMO, etc.), train a machine learning model to predict measurements for a design pattern, or other lithography or metrology related applications. As the evaluation process herein ensures the given pattern set has sufficient coverage of the design layout, only a reduced amount measurements may be made thereby saving a substantial amount of metrology time. Thus, throughput of the patterning process can be improved.

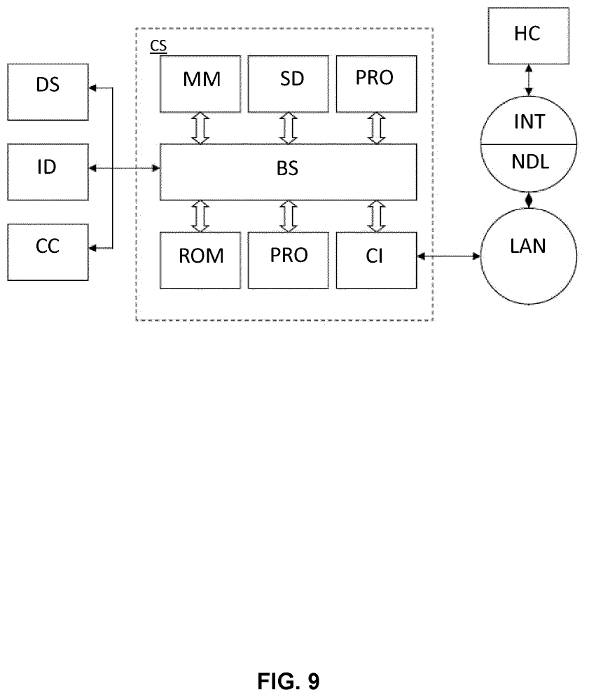

In an embodiment, the methods discussed herein may be provided as one or more computer program products or a non-transitory computer readable medium having instructions recorded thereon, the instructions when executed by a computer implementing the operation of the method 400 discussed above. For example, an example computer system CS in FIG. 9 includes a non-transitory computer-readable media (e.g., memory) comprising instructions that, when executed by one or more processors (e.g., 104), cause operations for evaluating any given set of patterns of a design layout. For example, evaluating a user-provided set of patterns, or a set of patterns selected using different pattern selection methods.

According to present disclosure, the combination and sub-combinations of disclosed elements constitute separate embodiments. For example, a first combination includes evaluating a selected pattern set by training a machine learning model using a selected pattern set. The sub-combination may include evaluating the selected pattern for pattern coverage. In another combination, determining risk patterns based on C2C differences. The sub-combination may include employing a reference model to determine the C2C difference.

FIG. 9 is a block diagram of an example computer system CS, according to an embodiment. Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

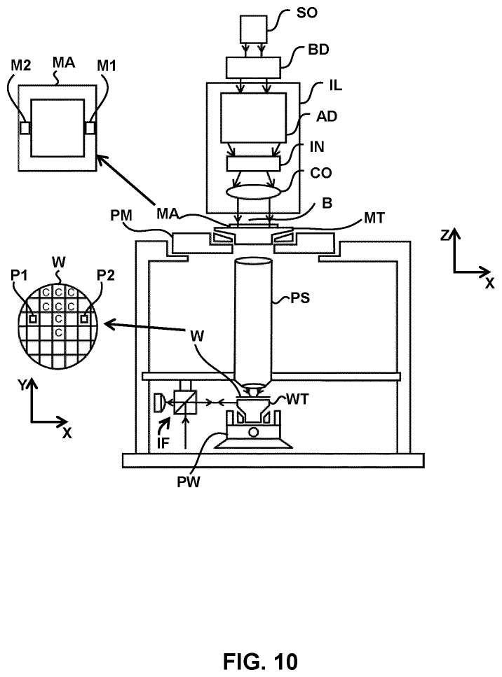

FIG. 10 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning means (and interferometric measuring means IF), the substrate table WT can be moved accurately, e.g. so as to position different target portions C in the path of beam PB. Similarly, the first positioning means can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

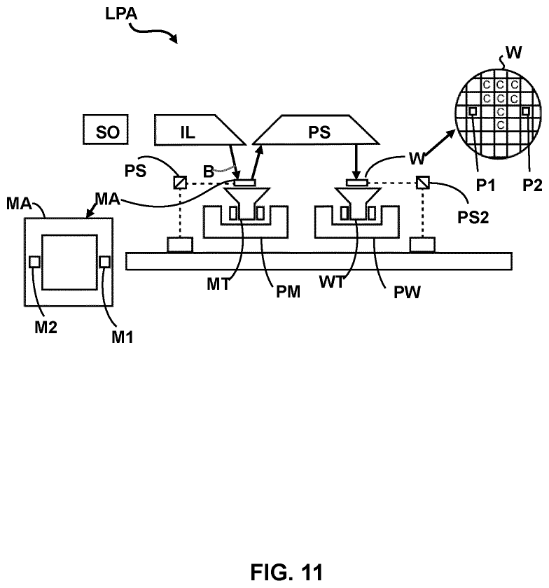

FIG. 11 is a schematic diagram of another lithographic projection apparatus (LPA), according to an embodiment.

LPA can include source collector module SO, illumination system (illuminator) IL configured to condition a radiation beam B (e.g. EUV radiation), support structure MT, substrate table WT, and projection system PS.

Support structure (e.g. a patterning device table) MT can be constructed to support a patterning device (e.g. a mask or a reticle) MA and connected to a first positioner PM configured to accurately position the patterning device;

Substrate table (e.g. a wafer table) WT can be constructed to hold a substrate (e.g. a resist coated wafer) W and connected to a second positioner PW configured to accurately position the substrate.

Projection system (e.g. a reflective projection system) PS can be configured to project a pattern imparted to the radiation beam B by patterning device MA onto a target portion C (e.g. comprising one or more dies) of the substrate W.

As here depicted, LPA can be of a reflective type (e.g. employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultra violet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g. patterning device table) MT and the substrate table WT are scanned synchronously while a pattern imparted to the radiation beam is projected onto target portion C (i.e. a single dynamic exposure). The velocity and direction of substrate table WT relative to the support structure (e.g. patterning device table) MT may be determined by the (de-) magnification and image reversal characteristics of the projection system PS.

In stationary mode, the support structure (e.g. patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

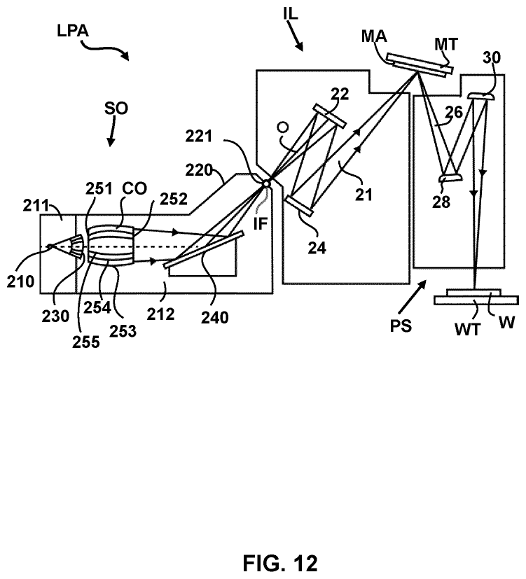

FIG. 12 is a detailed view of the lithographic projection apparatus, according to an embodiment.

As shown, LPA can include the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

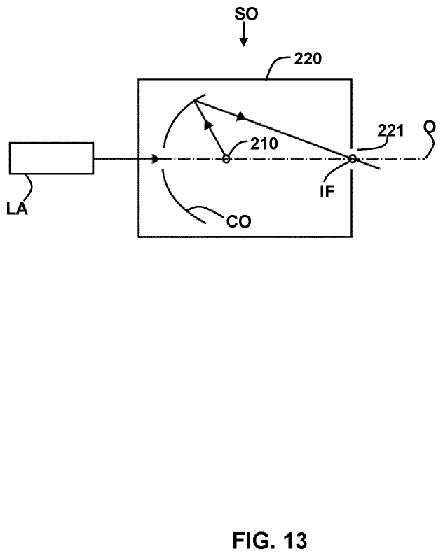

FIG. 13 is a detailed view of source collector module SO of lithographic projection apparatus LPA, according to an embodiment.

Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses:
1. A non-transitory computer-readable medium having instructions recorded thereon, the instructions when executed by a computer implementing a method for evaluating a selected set of patterns, the method comprising:
   obtaining (i) a first pattern set resulting from a pattern selection process, (ii) first pattern data associated with the first pattern set, (iii) characteristic data associated with the first pattern data, and (iv) second pattern data associated with a second pattern set;
   training a machine learning model based on the characteristic data associated with the first pattern, the machine learning model being configured to predict pattern data for a pattern input into the machine learning model;
   generating predicted second pattern data of the second pattern set by inputting the second pattern set to the trained machine learning model; and
   evaluating the first pattern set by comparing the second pattern data and the predicted second pattern data.
2. The medium of clause 1, wherein obtaining the first pattern data comprises:
   generating first contours or first images by executing a reference model configured to simulate a patterning process using the first pattern set as input.
3. The medium of clause 1, wherein obtaining the first pattern data and the second pattern data comprise:
   obtaining contours or images from metrology images of a patterned substrate comprising the first pattern set and the second pattern set.
4. The medium of clause 1, wherein the first pattern set comprises a first plurality of patterns of a design layout, and the second pattern set comprises a second plurality of patterns of the design layout.
5. The medium of clause 4, wherein the first pattern set is a subset of the second pattern set.
6. The medium of clause 1, wherein the second pattern data comprises second contours or second images generated by executing the reference model using the second pattern set as input, wherein the reference model is configured to simulate a patterning process.
7. The medium of clause 1, wherein the second pattern set comprises more patterns than the first pattern set.
8. The medium of clause 1, wherein the second pattern set comprises a full chip layout.
9. The medium of clause 1, wherein the characteristic data comprises data of gauges generated from the first pattern data, the gauges being configured to quantify one or more physical characteristic of a pattern.
10. The medium of clause 9, wherein the gauges comprise:
   edge placement gauges located at a plurality of locations along a contour of the first pattern data;
   critical dimension (CD) gauges configured to measure CD values of the first pattern set;
   gauges configured to measure lines in the first pattern set;
   gauges configured to measure spaces between features of the first pattern set;
   gauges configured to measure tip-to-tip structures; and/or
   gauges configured to measure contour differences between a model predicted contour and a design contour.
11. The medium of clause 1, wherein evaluating of the first pattern set comprises:
   computing a difference between the second pattern data and the predicted second pattern data.
12. The medium of clause 11, wherein evaluating of the first pattern set comprises:
   determining whether the difference breaches a difference threshold; and
   responsive to the difference not breaching of the difference threshold, classifying the first pattern set as acceptable for performing metrology.
13. The medium of clause 12, wherein evaluating of the first pattern set comprises:
   determining an absolute pattern coverage as a function of an absolute error associated with the trained machine learning model trained using the first pattern set.
14. The medium of clause 12, wherein evaluating of the first pattern set comprises:
   determining a relative pattern coverage as a function of a relative error, the relative error being a comparison between a first error range associated with the trained machine learning model trained using the first pattern set, and a second error range associated with another pattern set.
15. The medium of clause 12, further comprising:
   based on the evaluating, determining risk patterns within a design layout, the risk patterns being associated with model prediction errors breaching a desired error threshold;
   supplementing the first pattern set with the risk patterns.
16. The medium of clause 12, further comprising:
   identifying, based on the first pattern set, a list of patterns to be examined by a metrology tool.
17. The medium of clause 16, wherein the metrology tool determines metrology measurements comprising at least one of: critical dimension, overlay, and edge placement error associated with the first pattern set patterned on the substrate.
18. The medium of clause 12, further comprises:
   identifying locations of the second pattern set corresponding to breach in the difference threshold,
   supplementing the first pattern set with one or more patterns associated with the identified locations, the supplemented first pattern set having a higher pattern coverage compared to the first pattern set; and
   training another machine leaning model using the supplemented first pattern set.
19. The medium of clause 1, wherein the machine learning model is a convolutional neural network.
20. The medium of clause 2, wherein the reference model comprises one or more models characterizing the patterning process.
21. The medium of clause 20, wherein the reference model comprises a source model, an optics model, a resist model, an etch model, or a combination thereof.
22. The medium of clause 21, wherein the first pattern data, the second pattern data, and the predicted second pattern data comprise at least one of:
   an aerial image or contours extracted therefrom,
   a mask image or contours extracted therefrom;
   a resist image or resist contours extracted therefrom; and
   an etch image or contours extracted therefrom.
23. The medium of clause 22, wherein the reference model is a calibrated non-machine learning model.
24. The medium of clause 1, further comprising:
   determining, via the trained machine learning model, improvements to the patterning process.
25. The medium of clause 24, wherein determining improvements comprises:
   determining, via simulating a patterning process using the trained machine learning model, optical proximity corrections for a mask pattern associated with the patterning process;
   determining, via simulating the patterning process using the trained machine learning model, source mask optimization associated with the patterning process; and/or
   improving, via simulating the patterning process using the trained machine learning model, pattern fidelity matching of patterns printed on the substrate with patterns of a design layout.
26. A method for evaluating a selected set of patterns, the method comprising:
   obtaining (i) a first pattern set resulting from a pattern selection process, (ii) first pattern data associated with the first pattern set, (iii) characteristic data associated with the first pattern data, and (iv) second pattern data associated with a second pattern set;
   training a machine learning model based on the characteristic data associated with the first pattern, the machine learning model being configured to predict pattern data for a pattern input into the machine learning model;
   generating predicted second pattern data of the second pattern set by inputting the second pattern set to the trained machine learning model; and
   evaluating the first pattern set by comparing the second pattern data and the predicted second pattern data.
27. The method of clause 26, wherein obtaining the first pattern data comprises:
   generating first contours or first images by executing a reference model configured to simulate a patterning process using the first pattern set as input.
28. The method of clause 26, wherein obtaining the first pattern data and the second pattern data comprise:
   obtaining contours or images from metrology images of a patterned substrate comprising the first pattern set and the second pattern set.
29. The method of clause 26, wherein the first pattern set comprises a first plurality of patterns of a design layout, and the second pattern set comprises a second plurality of patterns of the design layout.
30. The method of clause 29, wherein the first pattern set is a subset of the second pattern set.
31. The method of clause 26, wherein obtaining the second pattern data comprises:
   generating second contours or second images by executing a reference model configured to simulate a patterning process using the second pattern set as input.
32. The method of clause 26, wherein the second pattern set comprises more patterns than the first pattern set.
33. The method of clause 26, wherein the second pattern set comprises a full chip layout.
34. The method of clause 26, wherein the characteristic data comprises gauges generated from the first pattern data, the gauges being configured to quantify one or more physical characteristic of a pattern.
35. The method of clause 34, wherein the gauges comprise:
   edge placement gauges located at a plurality of locations along a contour of the first pattern data;
   critical dimension (CD) gauges configured to measure CD values of the first pattern set;
   gauges configured to measure lines in the first pattern set;
   gauges configured to measure spaces between features of the first pattern set;
   gauges configured to measure tip-to-tip structures; and/or gauges configured to measure contour differences between a model predicted contour and a design contour.
36. The method of clause 26, wherein evaluating of the first pattern set comprises:
   computing a difference between the second pattern data and the predicted second pattern data.
37. The method of clause 36, wherein evaluating of the first pattern set comprises:
   determining whether the difference breaches a difference threshold; and
   responsive to the difference not breaching of the difference threshold, classifying the first pattern set as acceptable for performing metrology.
38. The method of clause 37, wherein evaluating of the first pattern set comprises:
   determining an absolute pattern coverage as a function of an absolute error associated with the trained machine learning model trained using the first pattern set.
39. The method of clause 37, wherein evaluating of the first pattern set comprises:
   determining a relative pattern coverage as a function of a relative error, the relative error being a comparison between a first error range associated with the trained machine learning model trained using the first pattern set, and a second error range associated with another pattern set.
40. The method of clause 37, wherein evaluating of the first pattern set comprises:
   determining risk patterns within a design layout, the risk patterns being associated with model prediction errors breaching a desired error threshold;
   supplementing the first pattern set with the risk patterns.
41. The method of clause 37, further comprising:
   identifying, based on the first pattern set, a list of patterns to be examined by a metrology tool.
42. The method of clause 41, wherein the metrology tool determines metrology measurements comprising at least one of: critical dimension, overlay, and edge placement error associated with the first pattern set patterned on the substrate.
43. The method of clause 37, further comprises:
   identifying locations of the second pattern set corresponding to breach in the difference threshold,
   supplementing the first pattern set with one or more patterns associated with the identified locations, the supplemented first pattern set having a higher pattern coverage compared to the first pattern set; and
   training another machine leaning model using the supplemented first pattern set.
44. The method of clause 26, wherein the machine learning model is a convolutional neural network.
45. The method of clause 27, wherein the reference model comprises one or more models characterizing the patterning process.
46. The method of clause 45, wherein the reference model comprises a source model, an optics model, a resist model, an etch model, or a combination thereof.
47. The method of clause 46, wherein the first pattern data and the second pattern data comprise at least one of:
   an aerial image or contours extracted therefrom,
   a mask image or contours extracted therefrom;
   a resist image or resist contours extracted therefrom; and
   an etch image or contours extracted therefrom.
48. The method of clause 47, wherein the reference model is a non-machine learning model.
49. The method of clause 26, further comprising:
   determining, via the trained machine learning model, improvements to the patterning process.
50. The method of clause 49, wherein determining improvements comprises:
   determining, via simulating a patterning process using the trained machine learning model, optical proximity corrections for a mask pattern associated with the patterning process;
   determining, via simulating the patterning process using the trained machine learning model, source mask optimization associated with the patterning process; and/or
   improving, via simulating the patterning process using the trained machine learning model, pattern fidelity matching of patterns printed on the substrate with patterns of a design layout.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. The descriptions herein are intended to be illustrative, not limiting. Thus, it will be apparent to one skilled in the art that modifications may be made as described without departing from the scope of the claims set out below.

1. A non-transitory computer-readable medium having instructions recorded thereon or therein, the instructions, when executed by a computer system, configured to cause the computer system to at least:
obtain (i) a first pattern set resulting from a pattern selection process, (ii) first pattern data associated with the first pattern set, (iii) characteristic data associated with the first pattern data, and (iv) second pattern data associated with a second pattern set;
train a machine learning model based on the characteristic data associated with the first pattern data, the machine learning model being configured to predict pattern data for a pattern input into the machine learning model;
generate predicted second pattern data of the second pattern set by input of the second pattern set to the trained machine learning model; and
evaluate the first pattern set by comparison of the second pattern data and the predicted second pattern data.

2. The medium of claim 1, wherein the instructions configured to cause the computer system to obtain the first pattern data are further configured to cause the computer system to generate first contours or first images by execution of a reference model configured to simulate a patterning process using the first pattern set as input.

3. The medium of claim 1, wherein the instructions configured to cause the computer system to obtain the first pattern data and the second pattern data are further configured to cause the computer system to obtain contours or images from metrology images of a patterned substrate comprising the first pattern set and the second pattern set.

4. The medium of claim 1, wherein the first pattern set is a subset of the second pattern set.

5. The medium of claim 2, wherein the second pattern data comprises second contours or second images generated by execution of the reference model using the second pattern set as input.

6. The medium of claim 1, wherein the characteristic data comprises data of gauges derived from the first pattern data, the gauges being configured to quantify one or more physical characteristic of patterns.

7. The medium of claim 6, wherein the gauges comprise:
edge placement gauges located at a plurality of locations along a contour of the first pattern data;
critical dimension (CD) gauges configured to measure CD values of the first pattern set;
gauges configured to measure lines in the first pattern set;
gauges configured to measure spaces between features of the first pattern set;
gauges configured to measure tip-to-tip structures; and/or
gauges configured to measure contour differences between a model predicted contour and a design contour.

8. The medium of claim 1, wherein the instructions configured to cause the computer system to evaluate the first pattern set are further configured to cause the computer system to determine an absolute pattern coverage as a function of an absolute error associated with the trained machine learning model trained using the first pattern set.

9. The medium of claim 1, wherein the instructions configured to cause the computer system to evaluate the first pattern set are further configured to cause the computer system to determine a relative pattern coverage as a function of a relative error, the relative error being a comparison between a first error range associated with the trained machine learning model trained using the first pattern set, and a second error range associated with another pattern set.

10. The medium of claim 1, wherein the instructions are further configured to cause the computer system to:
based on the evaluation of the first pattern set, determine risk patterns within a design layout, the risk patterns being associated with model prediction errors breaching an error threshold;
supplement the first pattern set with the risk patterns.

11. The medium of claim 1, wherein the instructions are further configured to cause the computer system to identify, based on the evaluation of the first pattern set, a list of patterns to be inspected by a metrology tool.

12. The medium of claim 1, wherein the instructions are further configured to cause the computer system to:
identify locations of the second pattern set corresponding to breach in a threshold of difference between the second pattern data and the predicted second pattern data;
supplement the first pattern set with one or more patterns associated with the identified locations, the supplemented first pattern set having a higher pattern coverage compared to the first pattern set; and
train another machine leaning model using the supplemented first pattern set.

13. The medium of claim 2, wherein the reference model comprises one or more models characterizing the patterning process, and wherein the reference model comprises one or more selected from: of a source model, an optics model, a resist model, an etch model.

14. The medium of claim 1, wherein the first pattern data, the second pattern data, and the predicted second pattern data comprise at least one selected from:
an aerial image or contours extracted therefrom,
a mask image or contours extracted therefrom;
a resist image or resist contours extracted therefrom; and
an etch image or contours extracted therefrom.

15. The medium of claim 2, wherein the reference model is a calibrated non-machine learning model.

16. The medium of claim 1, wherein the instructions are further configured to cause the computer system to:
determine, via simulation of a patterning process using the trained machine learning model, optical proximity corrections for a mask pattern associated with the patterning process;
determine, via simulation of the patterning process using the trained machine learning model, source mask optimization associated with the patterning process; and/or
improve, via simulation of the patterning process using the trained machine learning model, pattern fidelity matching of patterns printed on the substrate with patterns of a design layout.

17. A non-transitory computer-readable medium having instructions recorded thereon or therein, the instructions, when executed by a computer system, configured to cause the computer system to at least:
obtain second pattern data associated with a second pattern set;
generate predicted second pattern data of the second pattern set by input of the second pattern set to a trained machine learning model, the trained machine learning model trained based on characteristic data associated with first pattern data, wherein the first pattern data is associated with a first pattern set resulting from a pattern selection process and wherein the machine learning model is configured to predict pattern data for a pattern input into the machine learning model; and
evaluate the first pattern set by comparison of the second pattern data and the predicted second pattern data.

18. A method for evaluating a selected set of patterns, the method comprising:
obtaining (i) a first pattern set resulting from a pattern selection process, (ii) first pattern data associated with the first pattern set, (iii) characteristic data associated with the first pattern data, and (iv) second pattern data associated with a second pattern set;
training a machine learning model based on the characteristic data associated with the first pattern data, the machine learning model configured to predict pattern data for a pattern input into the machine learning model;
generating predicted second pattern data of the second pattern set by inputting the second pattern set to the trained machine learning model; and
evaluating the first pattern set by comparing the second pattern data and the predicted second pattern data.

19. The method of claim 18, wherein obtaining the first pattern data comprises generating first contours or first images by executing a reference model configured to simulate a patterning process using the first pattern set as input.

20. The method of claim 18, wherein obtaining the first pattern data and the second pattern data comprise obtaining contours or images from metrology images of a patterned substrate comprising the first pattern set and the second pattern set.
